(19) United States
(12) Patent Application Publication
(10) Pub. No.: US 2023/0148124 A1
(43) Pub. Date: May 11, 2023

(54) Apparatus for the Temperature Control of a Substrate and Corresponding Production Method

(71) Applicant: ERS Electronic GmbH, Germering (DE)

(72) Inventor: Klaus Reitinger, Germering (DE)

(21) Appl. No.: 18/149,755

(22) Filed: Jan. 4, 2023

Related U.S. Application Data
(63) Continuation of application No. 16/477,976, filed on Jul. 15, 2019.

(30) Foreign Application Priority Data
Jan. 16, 2017 (DE) 102017200588.2

(51) Int. Cl. H01L 21/67; G01R 1/04; H01L 21/08; H01L 21/673; C23C 16/458; C23C 14/54; H01J 37/32; C23C 16/46

(52) U.S. Cl. CPC H01L 21/67098; G01R 1/0458; H01L 21/08; H01L 21/67353; H01L 21/67242; H01L 21/67383; H01L 21/67248; H01L 21/67103; H01L 21/67109; C23C 16/4586; C23C 14/541; H01J 37/32724; C23C 16/463; C23C 14/50

(57) ABSTRACT

An apparatus for controlling the temperature of a substrate is equipped with a plate-type main body having a substrate placement area, a first temperature-control device for controlling the temperature of the main body using a first temperature-control fluid, having a first plurality of separate annular channels inside the main body, a second temperature-control device for controlling the temperature of the main body using a second temperature-control fluid, having a second plurality of separate annular channels inside the main body, wherein the first temperature-control fluid is supplied to the first plurality of annular channels through a first tube and removed therefrom through a second tube, wherein the second temperature-control fluid is supplied to the second plurality of annular channels through a third tube and removed therefrom through a fourth tube, wherein the main body has a first to fourth hole that communicate with the first plurality of separate annular channels and the second plurality of separate annular channels, wherein the first to fourth tubes are placed in the first to fourth holes of the main body.

### PRIORITY CLAIM

This application is a continuation of pending application Ser. No. 16/477,976, filed on Jul. 15, 2019, which is a 35 U.S.C. 371 National Stage application of PCT/EP2018/050874, filed Jan. 15, 2018, which claims priority to German Application No. DE 10 2017 200 588.2 filed on Jan. 16, 2017. The entire contents of the above-mentioned PCT and European patent applications are incorporated herein by reference as part of the disclosure of this U.S. application.

### BACKGROUND

The present invention relates to an apparatus for controlling the temperature of a substrate, in particular of a wafer substrate, and to a corresponding manufacturing method.

Although not limited thereto, the present invention and the problem on which it is based will be discussed with reference to integrated circuits at wafer level.

In the manufacturing flow during production of integrated circuits, wafer tests are performed on not yet diced wafers so that faulty integrated circuits can be detected early and removed. To this end, a wafer to be tested is placed into a wafer prober and brought to a desired test temperature using a temperature-controllable chuck located therein (apparatus for controlling the temperature of the wafer substrate). Once the wafer is at the desired test temperature, a contact needle arrangement located on a needle head is used to establish an electrical connection with the contact pads of the integrated circuit to be tested. The needle head having the contact needles is arranged on what is known as a probe card, which forms an interface between a testing system and the wafer via the contact needles of the needle head.

Wafer tests are typically performed in a temperature range between −40° C. and 200° C., in exceptional cases even at more extreme temperatures above or below zero.

Conventional apparatuses for controlling the temperature of a substrate, in particular of a wafer substrate, are provided with a closed cooling circuit, in which a cooling fluid circulates through channels in the substrate holder to a heat exchanger and back to the substrate holder.

EP 1 943 665 B1 discloses an apparatus for controlling the temperature of a substrate, in particular of a wafer, wherein the apparatus has a main body which is temperature-controlled by a first temperature-control device and a second temperature-control device, wherein the first temperature-control device is configured for controlling the temperature of the main body in a first temperature range between a first temperature and a second temperature, with the first temperature being lower than the second temperature, and is temperature-controlled using a first temperature-control fluid, and the second temperature-control device is configured for controlling the temperature of the main body in a second temperature range between a third temperature and a fourth temperature, with the third temperature being lower than the fourth temperature, and the second temperature-control device is temperature-controlled using a second temperature-control fluid, with the second temperature being lower than the fourth temperature and the first temperature-control fluid being different from the second temperature-control fluid. The main body has a substantially planar placement area having an attachment device, for attaching a substrate, which has a multiplicity of suction grooves, wherein one or more first temperature-control means channels for the first temperature-control fluid are provided inside the main body, which is located thereabove, and wherein the second temperature-control device for controlling the temperature of the main body comprises a temperature-control body that has, in its interior, one or more second temperature-control means channels for the second temperature-control fluid.

It has been found disadvantageous in this known apparatus for controlling the temperature of a substrate that it has a high volume due to the temperature-control devices that are located one above the other and that the lower temperature-control device is arranged far remote from the substrate.

### SUMMARY OF THE DISCLOSURE

It is therefore an object of the present invention to provide an apparatus for controlling the temperature of a substrate which can be designed to be more compact, and a corresponding manufacturing method.

In order to achieve this object, the present invention provides an apparatus for controlling the temperature of a substrate and a corresponding manufacturing method.

The idea on which the present invention is based consists of embedding two different temperature-control devices in the main body in a space-saving and easily connectable manner. In particular, the respective distances of the temperature-control devices from the substrate can be set to be approximately equal in the apparatus for controlling the temperature of a substrate in accordance with the invention.

In accordance with a further preferred development, the main body has a plate-type bottom part and a plate-type top part, which are connected, in particular soldered or adhesively bonded, together in a connection region. This simplifies the manufacturing method.

In accordance with a further preferred embodiment, the first to fourth holes are provided in the bottom part, and the first plurality of separate annular channels and the second plurality of separate annular channels are provided in the top part. The tubes can thus be placed prior to the assembly of the top part and the bottom part.

In accordance with a further preferred embodiment, the first plurality of separate annular channels and the second plurality of separate annular channels are arranged concentrically with respect to a central axis of the main body, preferably circularly.

In accordance with a further preferred embodiment, the first plurality of separate annular channels and the second plurality of separate annular channels are arranged such that they encircle each other in alternation. In this way, it is possible to achieve a homogeneous temperature distribution by way of both temperature-control devices.

In accordance with a further preferred embodiment, the first plurality of separate annular channels and the second plurality of separate annular channels have respective different cross sections. It is possible in this way to take into consideration different viscosities of the two temperature-control fluids, e.g. gas/liquid.

In accordance with a further preferred embodiment, the first to fourth tubes are soldered or adhesively bonded to the main body. This ensures a high tightness of both circuits.

In accordance with a further preferred embodiment, the first to fourth tubes are made from stainless steel, copper or plastics material.

In accordance with a further preferred embodiment, the main body is made of copper or aluminium. This ensures a high thermal conductivity. For specific applications, highly thermally conductive ceramic materials would also be feasible.

In accordance with a further preferred embodiment, the first openings and the second openings are arranged in pairs such that they communicate with the respective annular channel at two sites that are arranged approximately equidistantly clockwise and anticlockwise along the respective annular channel. This ensures a homogeneous temperature distribution.

In accordance with a further preferred embodiment, the third openings and the fourth openings are arranged in pairs such that they communicate with the respective annular channel at two sites which are arranged approximately equidistantly clockwise and anticlockwise along the respective annular channel. This ensures homogeneous temperature distribution.

In accordance with a further preferred embodiment, the first and/or second and/or third and/or fourth tubes have a first, open end and a second, closed end, wherein the openings have a cross section that increases from the first, open end to the second, closed end. It is thus possible to compensate for the pressure drop occurring across the tubes.

In accordance with a further preferred embodiment, the first and/or second and/or third and/or fourth tubes have a plurality of openings per annular channel. It is thus possible to adjust the respective inflow and outflow directions, in particular to homogenize the temperature distributions.

In accordance with a further preferred embodiment, the plurality of openings are aligned in opposite directions of the associated annular channel. This results in a thermodynamically particularly effective counterflow inflow or outflow.

### DESCRIPTION OF THE DRAWINGS

Exemplary embodiments of the invention are illustrated in the drawings and explained in more detail in the following description.

FIG. 1 shows a schematic planar cross-sectional view of an apparatus for controlling the temperature of a substrate in accordance with a first embodiment of the present invention;

FIG. 2 shows a partial perpendicular cross-sectional view of the apparatus for controlling the temperature of a substrate in accordance with the first embodiment of the present invention along the line X_X′ in FIG. 1;

FIGS. 3a, 3b each show axial cross-sectional views of the first and second tubes of the apparatus for controlling the temperature of a substrate in accordance with the first embodiment of the present invention;

FIGS. 4a, 4b each show partial perpendicular cross-sectional views of the apparatus for controlling the temperature of a substrate in accordance with the first embodiment of the present invention in the region of the openings F1 and L3 for introducing the first or second temperature-control fluid;

FIGS. 4d, 4d each show partial perpendicular cross-sectional views of the apparatus for controlling the temperature of a substrate in accordance with the first embodiment of the present invention in the region of the openings F1′ and L3′ for removing the first or second temperature-control fluid;

FIG. 5 shows an axial cross-sectional view of the first tube of the apparatus for controlling the temperature of a substrate in accordance with a second embodiment of the present invention; and

FIG. 6 shows a partially perpendicular cross-sectional view of the apparatus for controlling the temperature of a substrate in accordance with a third embodiment of the present invention in the region of the openings F11 and L12 for introducing the first temperature-control fluid.

In the figures, identical reference symbols designate identical components or components having identical functions.

### DETAILED DESCRIPTION

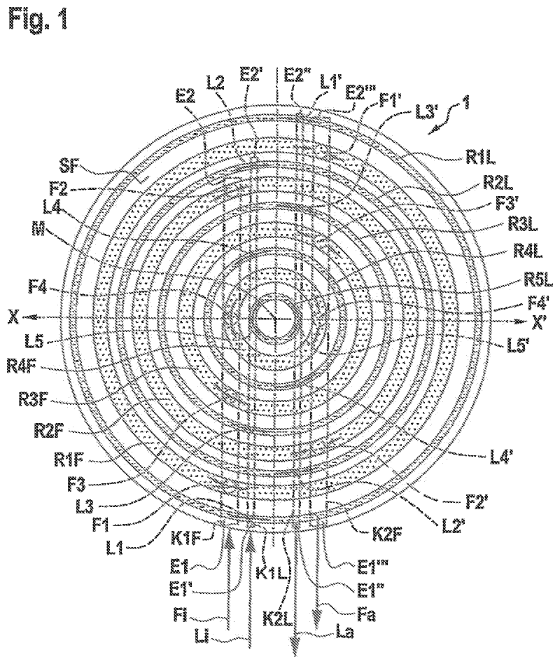

FIG. 1 is a schematic planar cross-sectional view of an apparatus for controlling the temperature of a substrate in accordance with a first embodiment of the present invention.

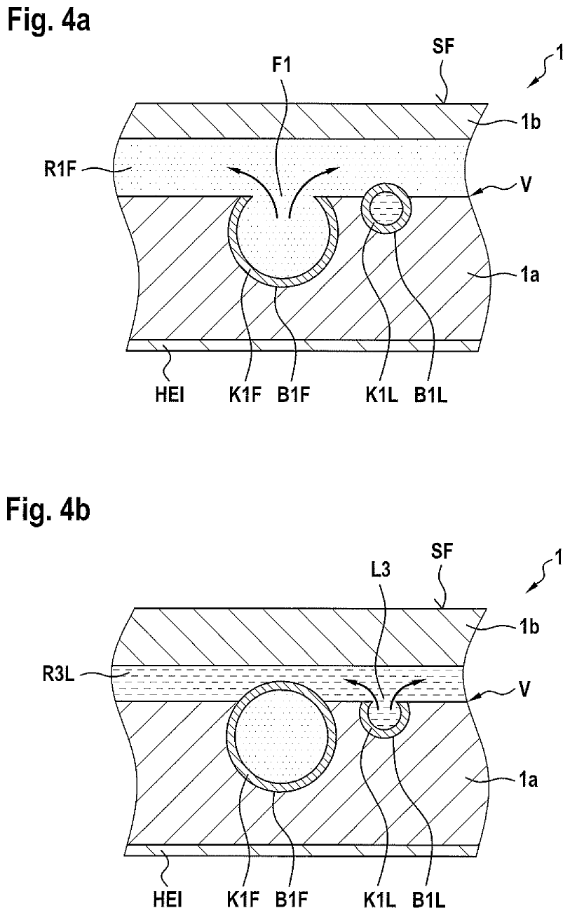

In FIG. 1, reference sign 1 designates a plate-type main body having a substrate placement area SF, which main body has a plate-type bottom part 1a and a plate-type top part 1b, which are connected to one another in a connection region V (cf. FIG. 4a)-b)), for example by way of soldering or adhesive bonding. The substrate placement area SF can have grooves (not illustrated) which are connected to a negative pressure generation apparatus (not illustrated) to serve for stabilizing the placed substrate, for example a wafer substrate.

Provided inside the plate-type main body 1 is a first temperature-control device for controlling the temperature of the main body using a first temperature-control fluid, for example liquid, having a first plurality of separate encircling annular channels R1F-R4F inside the main body 1 for circulating the first temperature-control fluid, with R1F designating a first channel, R2F designating a second channel, R3F designating a third channel and R4F designating a fourth channel of the first plurality.

Furthermore provided inside the main body 1 is a second temperature-control device for controlling the temperature of the main body 1 using a second temperature-control fluid, for example gas, having a second plurality of separate annular channels R1L-R5L inside the main body 1 for circulating the second temperature-control fluid, with R1L designating a first channel, R2L designating a second channel, R3L designating a third channel, R4L designating a fourth channel and R5L designating a fifth channel of the second plurality.

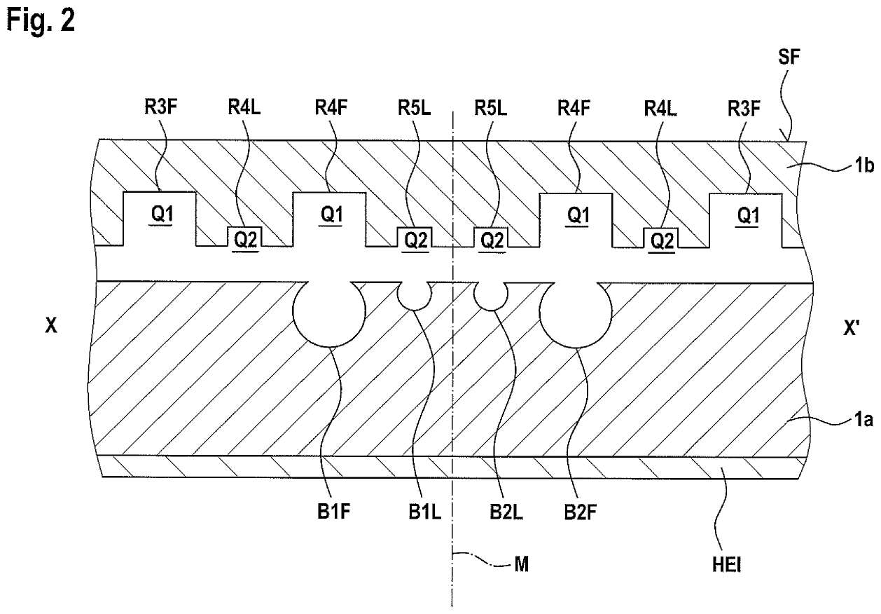

The first temperature-control fluid is able to be supplied to the first plurality of annular channels R1F-R4F through a first tube K1F and to be removed therefrom through a second tube K2F. The first tube K1F and the second tube K2F are placed in a corresponding first hole B1F and a corresponding second hole B2F of the main body 1 (cf. FIG. 2). The second temperature-control fluid is able to be supplied to the second plurality of annular channels R1L-R5L through a third tube K1L and to be removed therefrom through a fourth tube K2L. The third tube K1L and the fourth tube K2L are placed in a corresponding third hole B1L and fourth hole B2L in the main body 1 (cf. FIG. 2).

The entrance Fi for the first temperature-control fluid is located at a first, open end E1 of the first tube K1F, which furthermore has a second, closed end E2. The exit Fa for the first temperature-control fluid is located at a first, open end E1′″ of the second tube K2F, which furthermore has a second, closed end E2′″.

The entrance Li for the second temperature-control fluid is located at the first, open end E1′ of the third tube K1L, which furthermore has a second, closed end E2′. The exit La for the second temperature-control fluid is located at a first, open end E1″ of the fourth tube K2L, which furthermore has a second, closed end E2″.

The first to fourth tubes K1F, K2F, K1L, K2L are expediently additionally connected in a sealing manner to the main body 1, for example by way of adhesive bonding or soldering.

The first to fourth tubes K1F, K2F, K1L, K2L expediently project laterally out of the main body 1 such that corresponding connections, e.g. flanges (not illustrated), can be attached thereto, which are connected to corresponding sources and sinks for the first and second temperature-control fluid, respectively.

The first to fourth holes B1F, B2F, B1L, B2L, which in the present example are blind holes, in each case communicate with the first plurality of separate annular channels R1F-R4F and the second plurality of separate annular channels R1L-R5L, i.e. they are open towards them.

The first tube K1F, which is placed in the first hole B1F of the main body 1, has respective first openings F1-F4 in the region of the first plurality of separate annular channels R1F-R4F for supplying the first temperature-control fluid, with F1 designating a first opening, F2 designating a second opening, F3 designating a third opening and F4 designating a fourth opening of the first openings F1-F4.

The second tube K2F, which is placed in the second hole B2F of the main body 1, has respective second openings F1′-F4′ in the region of the first plurality of separate annular channels R1F-R4F for removing the first temperature-control fluid, with F1′ designating a first opening, F2′ designating a second opening, F3′ designating a third opening and F4′ designating a fourth opening of the second openings F1′-F4′.

The third tube K1L, which is placed in the third hole B1L of the main body 1, has respective third openings L1-L5 in the region of the second plurality of separate annular channels R1L-R5L for supplying the second temperature-control fluid, with L1 designating a first opening, L2 designating a second opening, L3 designating a third opening, L4 designating a fourth opening and L5 designating a fifth opening of the third openings L1-L5.

The fourth tube K2L, which is placed in the fourth hole B2L of the main body 1, has respective fourth openings L1′-L5′ in the region of the second plurality of separate annular channels R1L-R5L for removing the second temperature-control fluid, with L1′ designating a first opening, L2′ designating a second opening, L3′ designating a third opening, L4′ designating a fourth opening and L5′ designating a fifth opening of the fourth openings L1′-L5′.

In the present example, the first plurality of separate annular channels R1F-R4F and the second plurality of separate annular channels R1L-R5L are arranged circularly concentrically with respect to a central axis M of the main body 1. The first plurality of separate annular channels R1F-R4F and the second plurality of separate annular channels R1L-R5L are here arranged such that they encircle each other in alternation, with the result that a temperature distribution that is as homogeneous as possible is achievable.

The first to fourth tubes K1F, K2F, K1L, K2L are preferably made of stainless steel, copper or a plastics material, wherein the main body 1 is preferably made of copper or aluminium.

The first openings F1-F4 and the second openings F1′-F4′ are arranged in pairs such that they communicate with the respective annular channel R1F-R4F at two sites which are arranged approximately equidistantly clockwise and anticlockwise along the respective annular channel R1F-R4F, i.e. they are approximately diametrically opposite in the present circular geometry. The third openings L1-L5 and the fourth openings L1′-L5′ are arranged in pairs such that they communicate with the respective annular channel R1L-R5L at two sites which are arranged approximately equidistantly clockwise and anticlockwise along the respective annular channel R1L-R5L, i.e. they are approximately diametrically opposite in the present annular geometry.

This gives an inverse, substantially symmetric flow profile of the first and second temperature-control fluids.

FIG. 2 is a partial perpendicular cross-sectional view of the apparatus for controlling the temperature of a substrate in accordance with the first embodiment of the present invention along the line X_X′ in FIG. 1.

As can be seen in FIG. 2, in the present exemplary embodiment, the first to fourth holes B1F, B2F, B1L, B2L are provided in the bottom part 1a, and the first plurality of separate annular channels R1F-R4F and the second plurality of separate annular channels R1L-R5L are provided in the top part 1b. The first plurality of separate annular channels R1F-R4F are rectangular and have a first cross section Q1, and the second plurality of separate annular channels R1L-R5L are rectangular and have a second cross section Q2, with the second cross section Q2 being smaller than the first cross section. This takes into consideration the fact that the first temperature-control fluid, in this case a liquid, and the second temperature-control fluid, in this case a gas, have different viscosities.

As can furthermore be seen from FIG. 2, a plate-type heating device HEI is furthermore provided on the bottom part 1a of the main body 1, for example with an electric heating mechanism.

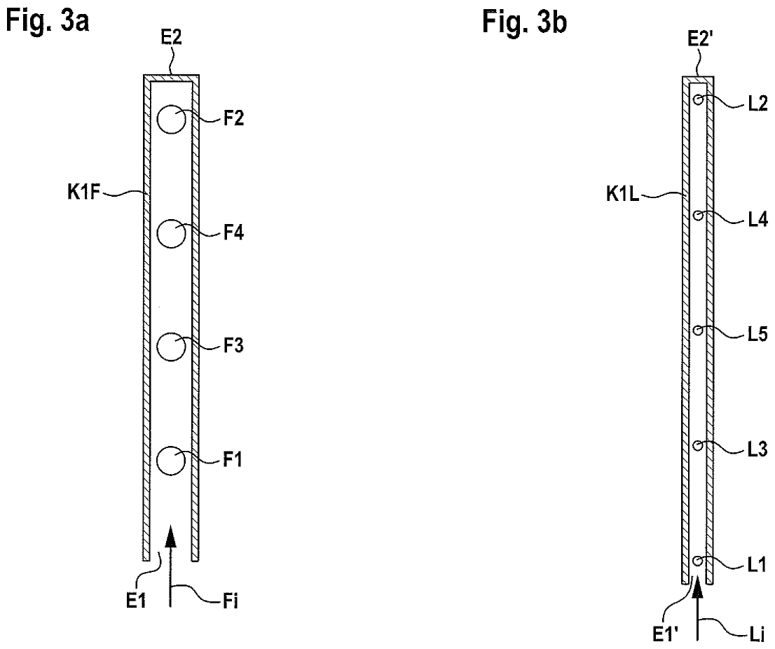

FIGS. 3a, 3b are in each case axial cross-sectional views of the first and second tubes of the apparatus for controlling the temperature of a substrate in accordance with the first embodiment of the present invention.

FIGS. 3a, 3b illustrate the first tube K1F and the third tube K1L in a state in which they are not placed in the main body 1. As can be seen in particular, the cross sections of the first openings F1-F4 are identical, as are the cross sections of the third openings L1-L5. However, the cross sections of the first openings F1-F4 are larger than the cross sections of the third openings L1-L5. This, too, takes into consideration the different viscosities of the first and second temperature-control fluids and can be adapted as necessary.

FIGS. 4a, 4b are respective partial perpendicular cross-sectional views of the apparatus for controlling the temperature of a substrate in accordance with the first embodiment of the present invention in the region of the openings F1 and L3 for introducing the first and second temperature-control fluids.

FIG. 4a) illustrates the intersection of the first tube K1F with the first annular channel R1F of the first plurality of annular channels R1F-R4F and the intersection of the third tube K1L with the first annular channel R1F of the first plurality of annular channels R1F-R4F. Since the first plurality of annular channels R1F-R4F is supplied by the first tube K1F, the latter is connected in the relevant region to the first annular channel R1F of the first plurality of annular channels R1F-R4F via the first opening F1 of the first openings F1-F4, whereas the third tube K1L in this region passes through in a sealing fashion, with the result that the first and second temperature-control fluids cannot mix. This is correspondingly true for the remaining first openings F2-F4, which are connected in each case to the associated channel R2F, R3F, R4F of the first plurality of annular channels R1F-R4F, whereas the third tube K1L in these regions likewise passes through in a sealing fashion.

In corresponding fashion, FIG. 4b) shows the intersection of the first tube K1F with the third annular channel R3L of the second plurality of annular channels R1L-R5L, where the first tube passes through in a sealing fashion. The third tube K1L in this region is open by way of the third opening L3 of the third openings L1-L5, so that the second temperature-control fluid can flow into the third annular channel R3L of the second plurality of annular channels R1L-R5L. This is correspondingly true for the remaining third openings L2-L5, which are each connected to the associated channel R2L, R3L, R4L, R5L of the second plurality of annual channels R1L-R5L, whereas the first tube K1F in these regions likewise passes through in a sealing fashion.

FIGS. 4c, 4d are in each case partial perpendicular cross-sectional views of the apparatus for controlling the temperature of a substrate in accordance with the first embodiment of the present invention in the region of the openings F1′ and L3′ for removing the first and second temperature-control fluid.

An analogous illustration is shown in FIG. 4c) for the removal of the first temperature-control fluid at the intersection of the fourth tube K2L and the second tube K2F with the first annular channel R1F of the first plurality of annular channels R1F-R4F, where the first temperature-control fluid can be removed through the first opening F1′ and the fourth tube K2L passes through in a sealing fashion. This is correspondingly true for the remaining third openings F2-F4, which are each connected to the associated channel R2F, R3F, R4F of the first plurality of annular channels R1F-R4F, whereas the fourth tube K2L in these regions likewise passes through in a sealing fashion.

Finally, FIG. 4d) shows the intersection of the fourth tube K2L with the third annular channel of the second plurality of annular channels R1L-R5L and the corresponding intersection of the second tube K2F. The second temperature-control fluid is removed here through the third opening L3′ into the fourth tube K2L, whereas the second tube passes through in a sealing fashion.

This is correspondingly true for the remaining third openings L1′-L5′, which are each connected to the associated channel R1L-R4L of the second plurality of annular channels R1L-R4L, whereas the second tube K2F in these regions likewise passes through in a sealing fashion.

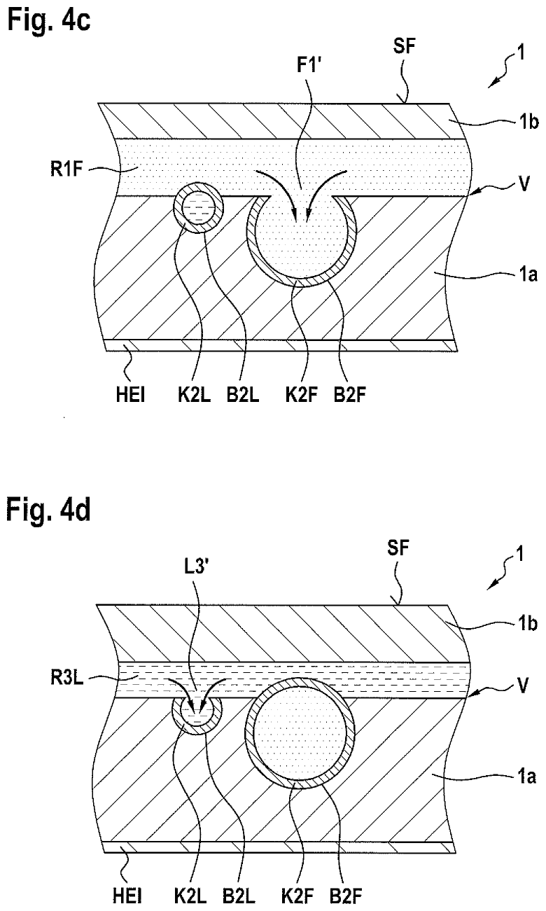

FIG. 5 is an axial cross-sectional view of the first tube of the apparatus for controlling the temperature of a substrate in accordance with a second embodiment of the present invention.

The second embodiment illustrates in accordance with FIG. 5 that the first openings F1a, F2a, F3a, F4a of the first tube K1F have different cross sections, wherein the cross sections of the openings F1a, F2a, F3a F4a increase from the first, open end E1 to the second, open end E2. This takes into consideration the decreasing dynamic pressure of the first temperature-control fluid.

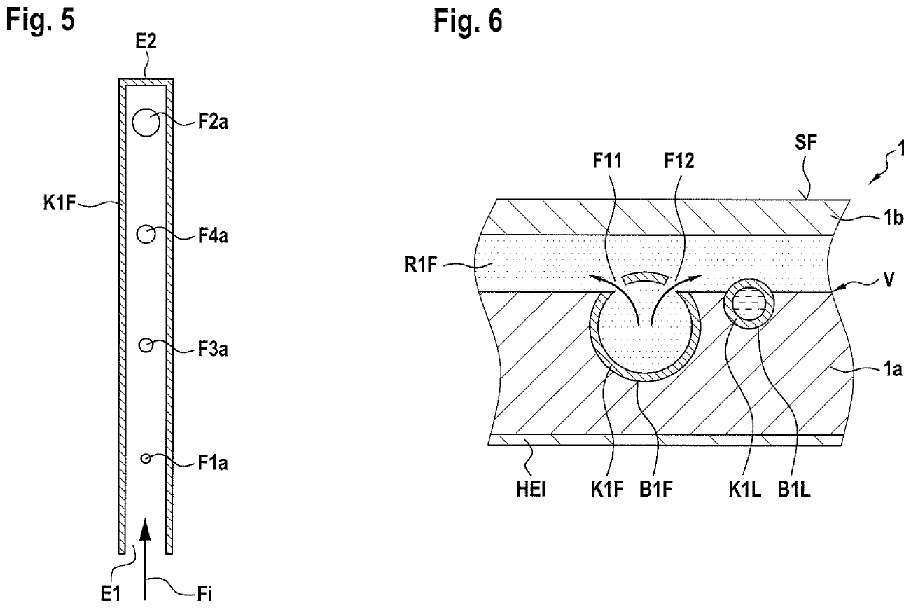

FIG. 6 is a partial perpendicular cross-sectional view of the apparatus for controlling the temperature of a substrate in accordance with a third embodiment of the present invention in the region of the openings F11 and L12 for introducing the first temperature-control fluid.

The third embodiment illustrates in accordance with FIG. 6 a modification, in which the first tube K1F has a plurality of openings F11, F12 per annular channel R1F-R4F of the first plurality of annular channels R1F-R4F. The outflow directions of the first temperature-control fluid can be influenced in this way and in particular hotspots, as they are known, above the tube in the top part 1b can be avoided.

In the present example, the openings F11 and F12 are aligned in opposite directions of the associated annular channel.

To produce the embodiments shown of the apparatus for controlling the temperature of a substrate, in particular of a wafer substrate, preferably first the holes B1F, B2F, B1L, B2L are made in the bottom part 1a of the main body, and subsequently the first to fourth tubes K1F, K2F, K1L, K4L are placed, aligned and sealed therein accordingly.

The first and second plurality of annular channels R1F-R4F and R1L-R5L are furthermore milled into the top part 1b. Subsequently, alignment and assembly and adhesive bonding or soldering are performed in the connection region V, which ultimately results in the above-described apparatus.

An alternative production method would be for the main body to be produced using a three-dimensional printing method, wherein the first to fourth tubes K1F, K2F, K1L, K2L are placed for example in an intermediate step after finishing the bottom part 1a.

Although the present invention has been explained here with reference to preferred embodiments, it is not limited thereto, but is modifiable in various ways.

The first to fourth holes B1F, B2F, B1L, B2L in the present case are blind holes, although the invention is not limited thereto and instead, these holes can also be configured to pass through, and the tubes K1F, K2F, K1L, K2L can be either open on both sides with two connections in each case, or open on only one side, as above.

In particular, the geometric shape of the apparatus for controlling the temperature of a substrate is not limited to a round shape either, but can have any desired geometry. The stated materials are also only examples and can be widely varied. The geometric configuration of the channel system is also modifiable as desired.

1. Apparatus for controlling the temperature of a wafer substrate, comprising:
a top plate having opposite top and bottom surfaces, said top surface defining a substrate placement area and said bottom surface defining a first mating surface, said top plate including a plurality of annular channels defined concentrically about a central axis, said plurality of annular channels open at said mating surface; and
a bottom plate having opposite top and bottom surfaces, said top surface defining a second mating surface configured for sealed connection with said first mating surface, said bottom plate defining first and second elongated holes extending linearly along said second mating surface so that each of said first and second elongated holes is open at said second mating surface along the length of each elongated hole, wherein each of said first and second elongated holes intersects and is in direct fluid communication with each of a first plurality of channels of said plurality of annular channels.

2. The apparatus of claim 1, wherein said central axis is disposed between said first and second elongated holes.

3. The apparatus of claim 1, wherein said bottom plate further defines third and fourth elongated holes extending linearly along said second mating surface so that each of said third and fourth elongated holes is open at said second mating surface along the length of each elongated hole, wherein each of said third and fourth elongated holes intersects and is in direct fluid communication with each of a second plurality of channels of said plurality of annular channels.

4. The apparatus of claim 2, wherein said central axis is disposed between said first and second elongated holes, and between said third and fourth elongated holes.

5. The apparatus of claim 4, wherein said third and fourth elongated holes are disposed between said first and second elongated holes.

6. The apparatus of claim 5, wherein said plurality of elongated holes includes an innermost annular channel;
said first plurality of channels does not include said innermost annular channel; and
said second plurality of channels includes said innermost annular channel.

7. The apparatus of claim 1, wherein:
each of said plurality of channels has a cross-section in the direction of fluid flow therethrough; and
said plurality of channels includes a first group of annular channels having a first cross-section and a different second group of annular channels having a second cross-section different from said first cross-section.

8. The apparatus of claim 1, wherein the cross-section of said plurality of channels is rectangular.

9. The apparatus of claim 1, wherein the first group of channels and the second group of channels are arranged such that they encircle each other in alternation.

10. The apparatus of claim 1, wherein the top plate and bottom plate are made of copper or aluminium.

11. Apparatus for controlling the temperature of a wafer substrate, comprising:
a top plate having opposite top and bottom surfaces, said top surface defining a substrate placement area and said bottom surface defining a first mating surface, said top plate defining a plurality of concentric annular channels open at said mating surface;
a bottom plate having opposite top and bottom surfaces, said top surface defining a second mating surface configured for sealed connection with said first mating surface, said bottom plate defining first and second elongated holes extending linearly along said second mating surface so that each of said first and second elongated holes is open at said second mating surface along the length of each elongated hole, wherein each of said first and second elongated holes intersects and is in direct fluid communication with a first plurality of channels of said plurality of concentric annular channels;
a first elongated tube disposed within said first elongated hole, said first tube having an open end for receiving a temperature-control fluid and an opposite closed end, said first elongated tube defining a first number of openings between said open end and said closed end, said first elongate tube arranged in said first elongated hole with each of said first number of openings in direct fluid communication with a first number of corresponding channels of said first plurality of channels; and
a second elongated tube disposed within said second elongated hole, said second tube having an open end for discharging a temperature-control fluid and an opposite closed end, said second elongated tube defining a like first number of openings between said open end and said closed end, said second elongate tube arranged in said second elongated hole with each of said like first number of openings in direct fluid communication with said first number of corresponding channels,
whereby temperature-control fluid entering said first elongated tube flows through each of said first number of openings in said first elongated tube, into each first number of corresponding channels and through each first number of corresponding channels to said like first number of openings in said second elongated tube for discharge at the open end of said second elongated tube.

12. The apparatus of claim 11, wherein said first number of openings in said first elongated tube and said like first number of openings in said second elongated tube includes at least two openings in direct fluid communication with at least two corresponding channels of said first plurality of channels.

13. The apparatus of claim 11, wherein said first and second elongated holes are arranged so that each first number of openings and like first number of openings intersect the same corresponding channel at diametrically opposite positions on the same corresponding channel.

14. The apparatus of claim 11, further comprising:
third and fourth elongated holes defined in said bottom plate and extending linearly along said second mating surface so that each of said third and fourth elongated holes is open at said second mating surface along the length of each elongated hole, wherein each of said third and fourth elongated holes intersects and is in direct fluid communication with a second plurality of channels of said plurality of concentric annular channels;
a third elongated tube disposed within said third elongated hole, said third tube having an open end for receiving a temperature-control fluid and an opposite closed end, said third elongated tube defining a second number of openings between said open end and said closed end, said third elongate tube arranged in said third elongated hole with each of said second number of openings in direct fluid communication with a second number of corresponding channels of said second plurality of channels; and
a fourth elongated tube disposed within said fourth elongated hole, said fourth tube having an open end for discharging a temperature-control fluid and an opposite closed end, said fourth elongated tube defining a like second number of openings between said open end and said closed end, said fourth elongate tube arranged in said fourth elongated hole with said like second number of openings in direct fluid communication with said second number of corresponding channels,
whereby temperature-control fluid entering said third elongated tube flows through each of said second number of openings, into each second number of corresponding channels and through each second number of corresponding channels to said like second number of openings in said fourth elongated tube for discharge at the open end of said fourth elongated tube.

15. The apparatus of claim 14, wherein:
said first number of openings in said first elongated tube and said like first number of openings in said second elongated tube includes at least two openings in direct fluid communication with at least two corresponding channels of said first plurality of channels; and
said second number of openings in said third elongated tube and said like second number of openings in said fourth elongated tube includes at least two openings in direct fluid communication with at least two corresponding channels of said second plurality of channels.

16. The apparatus of claim 15, wherein said at least two corresponding channels of said first plurality of channels is different from said at least two corresponding channels of said second plurality of channels.

17. The apparatus of claim 14, wherein:
each of said plurality of channels has a cross-section in the direction of fluid flow therethrough;
said plurality of channels includes a first group of annular channels having a first cross-section and a different second group of annular channels having a second cross-section different from said first cross-section;
said first number of openings and said like first number of openings are in direct fluid communication only with said first group of annular channels; and
said second number of openings and said like second number of openings are in direct fluid communication only with said second group of annular channels.

18. The apparatus of claim 17, wherein the first group of channels and the second group of channels are arranged such that they encircle each other in alternation.

19. The apparatus of claim 11, wherein the cross-section of said plurality of channels is rectangular.

20. The apparatus of claim 11, wherein:
the first number of openings and said like first number of openings includes two or more openings spaced apart between the open end and the opposite closed end of the respective first and second elongated tubes; and
said two or more openings of each of said first and second elongated tubes increase in size from the open end to the opposite closed end.
